(19) United States
(12) Patent Application Publication
(10) Pub. No.: US 2026/0002263 A1
(43) Pub. Date: Jan. 1, 2026

(54) DEPOSITION QUALITY CONTROL METHOD AND DEPOSITION QUALITY CONTROL SYSTEM PERFORMING THE SAME

(71) Applicant: Samsung Display Co., LTD., Yongin-si (KR)

(72) Inventor: SUNGMIN HUCH, Yongin-si (KR)

(21) Appl. No.: 19/202,163

(22) Filed: May 8, 2025

(30) Foreign Application Priority Data
Jul. 1, 2024 (KR) 10-2024-0086117

(51) Int. Cl. C23C 16/52; H10K 50/844; H10K 71/13

(52) U.S. Cl. CPC C23C 16/52; H10K 50/844; H10K 71/135

(57) ABSTRACT

A deposition quality control method includes: inputting information on a first deposition time, forming a (N−2)^{th} encapsulation on a (N−2)^{th} substrate and a (N−1)^{th} encapsulation on a (N−1)^{th} substrate during the first deposition time, measuring a deposition thickness each of a (N−2)^{th} encapsulation layer and a (N−1)^{th} encapsulation layer, calculating a compensation time which satisfies Equations 1 and 2 below, calculating a second deposition time by adding the compensation time to the first deposition time, and forming a (N)^{th} encapsulation layer on a (N)^{th} substrate during the second deposition time,

$$Y = AX + B , \qquad < Equation 1 >$$

where in Equation 1, Y denotes a deposition thickness of the (N)^{th} encapsulation layer, A denotes deposition rate, and X denotes the compensation time,

$$B = α * {D}_{2} + ( 1 - α ) * {D}_{1} , \qquad < Equation 2 >$$

where in Equation 2, D2 denotes the thickness of the (N−1)^{th} encapsulation layer, D1 denotes the thickness of the (N−2)^{th} encapsulation layer, and α denotes a weighted value.

This application claims priority to Korean Patent Application 10-2024-0086117, filed on Jul. 1, 2024, and all the benefits accruing therefrom under 35 U.S.C. § 119, the content of which in its entirety is herein incorporated by reference.

### BACKGROUND

### 1. Field

Embodiments relate to a deposition quality control method used in a manufacturing of a display device. More specifically, embodiments relate to a deposition quality control method and a deposition quality control system performing the deposition quality control method.

### 2. Description of the Related Art

With the development of information technology, the importance of display devices, which are the medium of connection between users and information, is being highlighted. As a result, the use of display devices such as liquid crystal display devices (“LCDs”), organic light-emitting display devices (“OLEDs”), and plasma display devices (“PDPs”) is increasing.

A manufacturing process of the display device may include a formation of various layers on a mother substrate. For example, a transistor may be formed on a substrate, a light-emitting layer may be formed on the transistor, and an encapsulation layer may be formed on the light-emitting layer. After forming the encapsulation layer, the mother substrate may be separated into individual plural cells by a cutting process.

The encapsulation layer is positioned on a path which travels the light emitted from the light-emitting layer, in a way such a thickness of the encapsulation layer may have an important effect on the light property of the display device.

### SUMMARY

Embodiments provide a deposition quality control method.

Other embodiments provide a deposition quality control system that performs the deposition quality control method.

A quality control method according to an embodiment includes: inputting information on a first deposition time; forming a (N−2)^{th} encapsulation layer on a (N−2)^{th} substrate during the first deposition time; measuring a deposition thickness of the (N−2)^{th} encapsulation layer; forming a (N−1)^{th} encapsulation layer on a (N−1)^{th} substrate during the first deposition time; measuring a deposition thickness of the (N−1)^{th} encapsulation layer; calculating a compensation time which satisfies Equation 1 and Equation 2 below; calculating a second deposition time by adding the compensation time to the first deposition time; and forming an (N)^{th} encapsulation layer on an (N)^{th} substrate during the second deposition time, (N)^{th} being a natural number greater than or equal to three,

$$Y = AX + B , \qquad < Equation 1 >$$

where in Equation 1, Y denotes a deposition thickness of the (N)^{th} encapsulation layer, A denotes a deposition rate, and X denotes the compensation time,

$$B = α * {D}_{2} + ( 1 - α ) * {D}_{1} \qquad < Equation 2 >$$

where in Equation 2, D2 denotes the thickness of the (N−1)^{th} encapsulation layer, D1 denotes the thickness of the (N−2)^{th} encapsulation layer, and α denotes a weighted value.

In an embodiment, each of the first to (N)^{th} encapsulation layers may be formed by inorganic material.

In an embodiment, the deposition quality control method may further include forming an organic light-emitting layer between each of the (N−2)^{th} substrate to the (N)^{th} substrate and a corresponding encapsulation layer, and the organic light-emitting layer may be covered by the corresponding encapsulation layer.

In an embodiment, each of the (N−2)^{th} to (N)^{th} encapsulation layers may have a multi-layer structure.

In an embodiment, the compensation time may include a first compensation time of a deposition time to form a first layer positioned most adjacent to the organic light-emitting layer among layers in the multi-layer structure and a second compensation time of the deposition time to form a second layer on the first layer among the layers in the multi-layer structure.

In an embodiment, the compensation time may include a compensation time of a deposition time to form a layer most adjacent to the organic light-emitting layer among layers in the multi-layer structure.

In an embodiment, the deposition quality control method may further include performing an inkjet process which discharges an organic material on the (N−2)^{th} to (N)^{th} substrates, after the forming the (N)^{th} encapsulation layer.

In an embodiment, each of the D1 and the D2 may be derived from a measured value of an ellipsometer.

In an embodiment, the ellipsometer may operate in a position adjacent to each of the (N−2)^{th} to (N)^{th} substrates, and the ellipsometer may measure the deposition thickness of each of the (N−2)^{th} to (N)^{th} encapsulation layers.

In an embodiment, the ellipsometer may operate using grease with a viscosity of about 500 to about 600 pascal-seconds.

A deposition quality control system according to an embodiment includes a deposition object including a substrate; a deposition chamber, which forms a first encapsulation layer on the substrate during a deposition time; a logistics chamber, which transports the deposition object after the formation of the first encapsulation layer; a thickness gauge which measures a deposition thickness of the first encapsulation layer positioned in the logistics chamber; and a controller which receives the deposition thickness of the first encapsulation layer from the thickness gauge and compensates the deposition time.

In an embodiment, the deposition object after the formation may include a (N−2)^{th} object, a (N−1)^{th} object, and a (N)^{th} object, and the (N−2)^{th} object may include a (N−2)^{th} encapsulation layer on a (N−2)^{th} substrate therein; the (N−1)^{th} object may include a (N−1)^{th} encapsulation layer on a (N−1)^{th} substrate therein; and the (N)^{th} object may include an (N)^{th} encapsulation layer on a (N−1)^{th} substrate therein, and each of the (N−2)^{th} encapsulation layer, the (N−1)^{th} encapsulation layer, and the (N)^{th} encapsulation layer may include an inorganic material.

In an embodiment, the controller may receive information on a first deposition time as an input, may commend to form the (N−2)^{th} encapsulation layer on the (N−2)^{th} substrate during the first deposition time, may commend to measure a deposition thickness of the (N−2)^{th} encapsulation layer, may commend to form the (N−1)^{th} encapsulation layer on the (N−1)^{th} substrate during the first deposition time, may commend to measure a deposition thickness of the (N−1)^{th} encapsulation layer, may calculate a compensation time which satisfies Equation 1 and Equation 2 below, may calculate a second deposition time by adding the compensation time to the first deposition time, and may commend to form the (N)^{th} encapsulation layer on the (N)^{th} substrate during the second deposition time, (N)^{th} being a natural number greater than or equal to three,

$$Y = AX + B , \qquad < Equation 1 >$$

where in Equation 1, Y denotes a deposition thickness of the (N)^{th} encapsulation layer, A denotes a deposition rate, and X denotes the compensation time,

$$B = α * {D}_{2} + ( 1 - α ) * {D}_{1} , \qquad < Equation 2 >$$

where in Equation 2, D2 denotes the thickness of the (N−1)^{th} encapsulation layer, D1 denotes the thickness of the (N−2)^{th} encapsulation layer, and α denotes a weighted value).

In an embodiment, the deposition object after the formation may further include an organic light-emitting layer between each of the (N−2)^{th} substrate to the (N)^{th} substrate and a corresponding encapsulation layer, and the organic light-emitting layer may be covered by the first to the corresponding encapsulation layers.

In an embodiment, each of the D1 and the D2 may be derived from a measured value of an ellipsometer.

In an embodiment, grease viscosity used for the ellipsometer operation may be about 500 to about 600 pascal-seconds.

In an embodiment, each of the (N−2)^{th} encapsulation layer, the (N−1)^{th} encapsulation layer, and the (N)^{th} encapsulation layer may have a multi-layer structure.

In an embodiment, the controller may derive a first compensation time of a deposition time to form a first layer positioned most adjacent to the organic light-emitting layer among layers in the multi-layer structure and a second compensation time of the deposition time to form a second layer on the first layer among the layers in the multi-layer structure.

In an embodiment, the controller may derive a compensation time of a deposition time to form an inorganic layer positioned most adjacent to the organic light-emitting layer among layers in the multi-layer structure.

In an embodiment, the deposition quality control system may further include an inkjet chamber which forms an organic encapsulation layer including an organic material on the deposition object after measuring the deposition thickness.

The deposition quality control method and the deposition quality control system according to embodiments of the disclosure may minimize deviation among the mother substrates by determining the deposition time of a next mother substrate based on the two mother substrates. By minimizing the deviation of the mother substrates, view angle color shift (“VACs”) property may be effectively improved.

In addition, the deposition quality control method and the deposition quality control system performing the deposition quality control method according to the embodiments may prevent a scattering of grease on the mother substrate by using a fume free grease or lubrication free driving device (e.g., linear driving device by magnetic method). Accordingly, an occurrence of an un-filled defect in a subsequent process (e.g., the inkjet process) using the grease may be prevented, and a reduction of yield (e.g., the reduction of yield due to a disposal of the display device which is of poor reliability) may be effectively prevented.

### BRIEF DESCRIPTION OF THE DRAWINGS

The above and other features of embodiments of the disclosure will become more apparent by describing in further detail embodiments thereof with reference to the accompanying drawings, in which:

FIG. 1 is a view illustrating a deposition quality control system according to an embodiment of the disclosure;

FIG. 2 is a view illustrating a first process chamber of FIG. 1;

FIG. 3 is a view illustrating a mask and a deposition object in the first process of FIG. 2;

FIG. 4 is a plan view illustrating the deposition object of FIG. 3;

FIG. 5 is a cross-sectional view taken along line I-I′ of FIG. 4;

FIG. 6 is a view illustrating a first inorganic encapsulation layer included in each of a plurality of cells of FIG. 5;

FIG. 7 is a view illustrating a thickness gauge of FIG. 1;

FIGS. 8, 9, and 10 are views illustrating an effect of the deposition quality control system of FIG. 1;

FIG. 11 is a flowchart is illustrating a deposition quality control method according to an embodiment of the disclosure; and

FIGS. 12, 13, 14, 15, 16, 17, 18, 19, and 20 are views illustrating the deposition quality control method of FIG. 11.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third”, “(N)^{th}” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

“About” or “substantially the same” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, 5% or 2% of the stated value.

The invention now will be described more fully hereinafter with reference to the accompanying drawings, in which various embodiments are shown. The drawings will use the same reference numerals for the same components, and duplicate descriptions of the same components will be omitted.

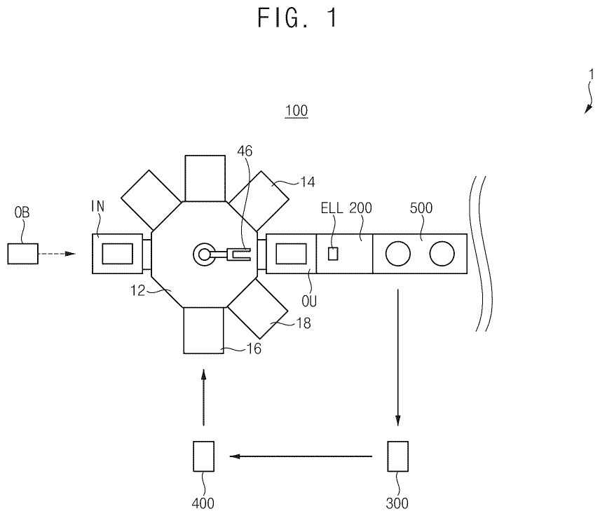

FIG. 1 is a view illustrating a deposition quality control system according to an embodiment of the disclosure.

Referring to FIG. 1, a deposition quality control system 1 according to an embodiment of the disclosure may include a deposition object OB, a deposition chamber 100, a logistics chamber 200, a thickness gauge ELL, a first controller 300, a second controller 400, and an inkjet chamber 500.

For example, the deposition chamber 100, the logistics chamber 200, and the inkjet chamber 500 may be connected to each other. Accordingly, a deposition process, a transport process, and an inkjet process may be performed in-line (i.e., sequential process).

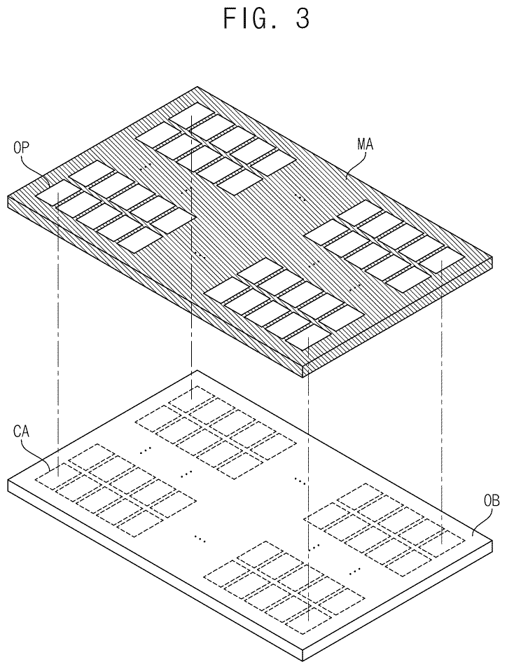

In an embodiment, the deposition object OB may include a substrate. For example, the substrate may be a mother substrate in which a plurality of cells are defined. Detailed features of the deposition object OB will be described below with reference to FIG. 3 et seq.

In an embodiment, in the deposition chamber 100, a first encapsulation layer may be formed on the substrate in the deposition object OB.

For example, through an inlet IN of the deposition chamber 100, the deposition object OB may be disposed in the deposition chamber 100. After the deposition object OB is disposed inside the deposition chamber 100, an interior of the deposition chamber 100 may remain closed from an outside air.

For example, a picker 46 may be disposed in the logistics chambers 12. The picker 46 may transport the deposition object OB into an empty process chamber.

For example, a process chamber may be provided in plural. For example, the plurality of process chambers may be connected to each other with the logistics chamber 12 at a center, and may be arranged in a cluster.

For example, the plurality of process chambers may include a first process chamber 16 and a second process chamber 18. For example, if the deposition process is in progress in the first process chamber 16, the deposition object OB entering the inlet IN is transported to the empty second process chamber 18, and the deposition process may be performed.

For example, the deposition object OB may be discharged outside of the deposition chamber 100 through an outlet OU. The picker 46 may transport the deposition object OB that has been deposited (i.e., the deposition object OB completed the deposition) to the outlet OU. For example, if the deposition process is completed first in the first process chamber 16, the deposition object OB in the first process chamber 16 may be discharged to the outlet OU in priority.

However, the disclosure is not limited thereto. For another example, the process chamber may be one, and a position, shape, or the like of the picker 46 may be variously changed.

In an embodiment, the logistics chamber 200 may transport the deposition object OB in which the formation of the first encapsulation layer (i.e., the deposition process) has been completed. For example, an organic encapsulation layer including an organic material may be formed on the first encapsulation layer. The logistics chamber 200 may transport the deposition object OB to the chamber (i.e., inkjet chamber 500)) to form the organic encapsulation layer.

In an embodiment, the thickness gauge ELL may measure a deposition thickness of the first encapsulation layer. Specifically, in an embodiment, the thickness gauge ELL may include an ellipsometer.

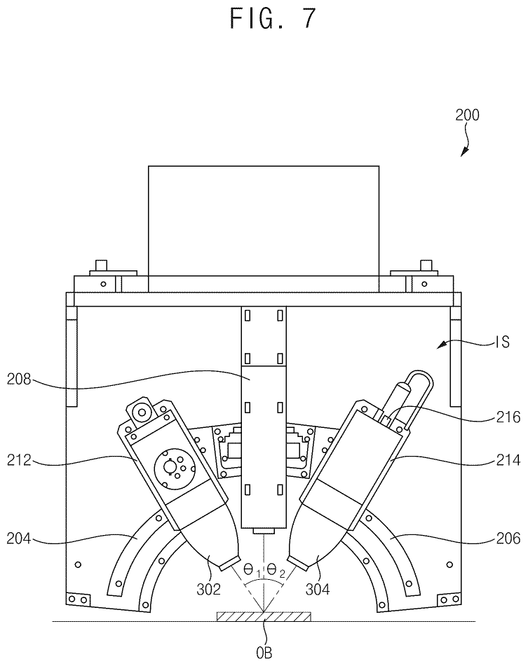

In an embodiment, the thickness gauge ELL may be positioned in the logistics chamber 200. Specifically, in an embodiment, the ellipsometer may be positioned between the deposition chamber 100 and the inkjet chamber 500. Detailed features of the thickness gauge ELL will be described below with reference to FIG. 7 et seq.

In an embodiment, the first controller 300 may receive information on the deposition thickness of the first encapsulation layer from the thickness gauge ELL and compensate a deposition time.

For example, the first controller 300 may collect data (e.g., the deposition thickness, or the like.) from each of the plural process chambers and compensate the deposition time of each of the plural process chambers.

In an embodiment, the first controller 300 may receive information on a first deposition time as an input, may commend to form an (N−2)^{th} encapsulation layer on a (N−2)^{th} substrate during the first deposition time, may commend to measure a deposition thickness of the (N−2)^{th} encapsulation layer, may commend to form a (N−1)^{th} encapsulation layer on a (N−1)^{th} substrate during the first deposition time, may commend to measure a deposition thickness of the (N−1)^{th} encapsulation layer, may calculate a compensation time which satisfies Equation 1 and Equation 2 below, may calculate a second deposition time by adding the compensation time to the first deposition time, and may commend to form a (N)^{th} encapsulation layer on a (N)^{th} substrate during the second deposition time. Here, (N)^{th} is a natural number greater than or equal to three.

$$Y = AX + B \qquad < Equation 1 >$$

In Equation 1, Y denotes the (target) thickness of the (N)^{th} encapsulation layer, A denotes deposition rate, and X denotes the compensation time.

$$B = α * {D}_{2} + ( 1 - α ) * {D}_{1} \qquad < Equation 2 >$$

In Equation 2, D2 denotes the thickness of the (N−1)^{th} encapsulation layer, D1 denotes the thickness of the (N−2)^{th} encapsulation layer, and α denotes a weighted value.

For example, in the deposition chamber 100, the first encapsulation layer may be formed on the first mother substrate (e.g., (N−2)^{th} substrate), the second encapsulation layer may be formed on the second mother substrate (e.g., (N−1)^{th} substrate), and the third encapsulation layer may be formed on the third mother substrate (e.g., (N)^{th} substrate). The first mother substrate, the second mother substrate, and the third mother substrate may be numbered according to an order in which the deposition was completed.

As described above, information on the first deposition time (e.g., an initial deposition time) may be inputted before performing the deposition process. And then, the deposition process may be performed sequentially on the (N−2)^{th} substrate and the (N−1)^{th} substrate during the first deposition time per each. The information on the first deposition time may be prestored in a memory located inside or outside the deposition quality control system 1.

For example, if N=3, the deposition process may be performed on the first substrate and the second substrate during the first deposition time per each. Accordingly, the first encapsulation layer may be formed on the first substrate, and the second encapsulation layer may be formed on the second substrate.

The first substrate and the second substrate may pass through the thickness gauge ELL sequentially. Accordingly, a first deposition thickness D1 of the first encapsulation layer and a second deposition thickness D2 of the second encapsulation layer may be measured.

The first deposition thickness D1 and the second deposition thickness D2 may be inserted into Equation 2, and the weighted value α may be adjusted to derive B. For example, the weighted value may be about 0.5. However, the disclosure is not limited thereto. For another example, the weighted value may be greater about zero and less than about one. The closer the weighted value is to about 1, the more the measured value of the deposition object OB in which the most recent deposition process has been completed may be reflected.

In a conventional deposition quality control system, the deposition thickness of a previous mother substrate may be used for the compensation of the deposition thickness of a next mother substrate. In this case, even if the deposition thickness is inaccurately measured due to an error of the deposition quality control system, and the deviation among the deviation of the mother substrate may be greater as the deposition thickness of the next mother is compensated based on an error (i.e. the inaccurately measured) value.

However, in the case of a deposition quality control system 1 according to an embodiment of the disclosure, the deposition thickness of the next mother substrate may be compensated based on the deposition thicknesses of the two mother substrates. In addition, the compensation may be performed by reflecting the weighted value to further reflect the deposition thickness closer to a true value. Accordingly, the deviation of the mother substrate may be minimized.

$$Y = AX + B \qquad < Equation 1 >$$

For example, the compensation time X of Equation 1 may be calculated by inserting the deposition rate to A, inserting the B derived from the Equation 2 to B, and inserting target thickness Y (e.g., about 3000 Ångström).

For example, the deposition rate may be a pre-stored value for each of the plurality of process chambers. For example, the deposition rate may mean the deposition thickness per unit time (unit: Ångström/sec or milli-sec).

The compensation time X may be a time to be added/subtracted from the first deposition time in order to minimize the thickness deviation. For example, if the first deposition time is about 60 seconds, and the X is calculated to be about −5 seconds, the next deposition process may be performed for about 55 seconds. As the deposition time is determined continuously, the deviation may be minimized.

In an embodiment, the second controller 400 may feedback the compensation time of the deposition time to the deposition chamber 100. As described above, the deposition chamber 100 may include a plurality of process chambers. To each of the plural process chambers, the second controller 400 may transmit a corresponding compensation time command.

In an embodiment, inkjet chamber 500 may form an organic encapsulation layer including an organic material on the deposition object OB on which the deposition thickness measurement has been completed.

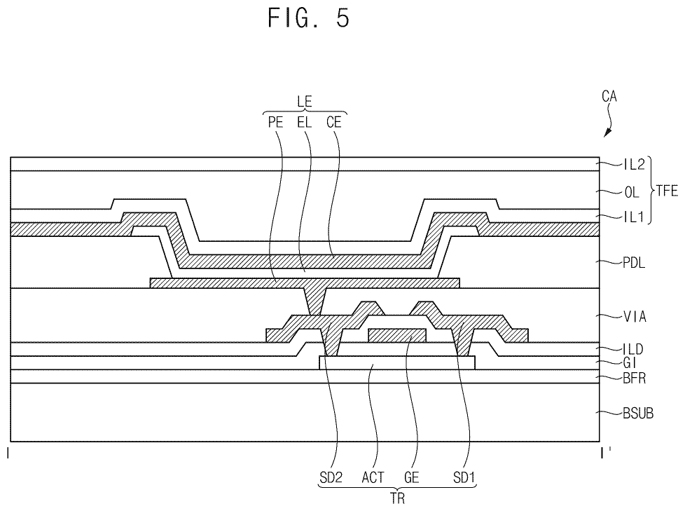

For example, the first encapsulation layer may include inorganic material, and the organic encapsulation layer may include organic material. Detailed features of the first encapsulation layer and the organic encapsulation layer will be described below with reference to FIG. 5 et seq.

However, the disclosure is not limited thereto. For example, the deposition quality control system of FIG. 1 may include more various components, or some of the components may be omitted/changed.

For example, the first controller 300 and the second controller 400 may be implemented as a single computer. For another example, the first controller 300 and the second controller 400 may be implemented as different programs within the single computer.

In the FIG. 1, described as one thickness gauge ELL is included. However, in another embodiment, multiple thickness gauges ELL may be provided. In this case, a compensation accuracy may be greater than if a measurement is done with a single thickness gauge ELL.

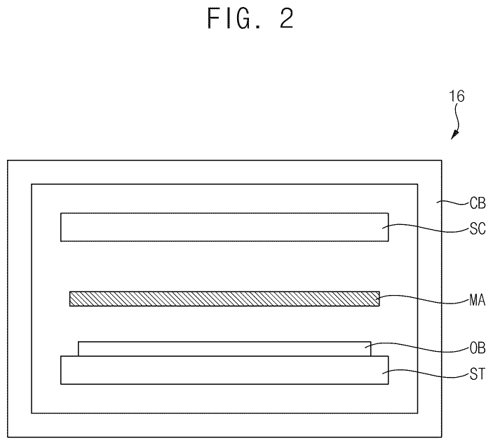

FIG. 2 is a view illustrating the first process chamber of FIG. 1. FIG. 3 is a view illustrating a mask and the deposition object disposed in the first process chamber of FIG. 2. Referring to FIGS. 2 and 3, the first process chamber 16 may include a chamber CB, a stage ST, a deposition source SC, and a mask MA.

The first process chamber 16 may be used in the manufacturing process of the display device. For example, the first process chamber 16 may be used in the deposition process to form a thin layer on the deposition object OB during the manufacturing process of the display device. In an embodiment, the deposition object OB may be a substrate. For example, the thin layer may be formed on the substrate through the deposition process using the first process chamber 16.

The substrate may mean the mother substrate comprising display devices under manufacture. The substrate may include at least one additional layer included in the display device. For example, the substrate may include at least one additional layer of an inorganic, organic or metal layer included in the display device.

In an embodiment, the first process chamber 16 may deposit the thin layer on the substrate by chemical vapor deposition (“CVD”). However, the disclosure is not limited thereto. For example, the first process chamber 16 may perform plasma-enhanced chemical vapor deposition (“PECVD”), low pressure chemical vapor deposition (“LPCVD”), metal-organic chemical vapor deposition (“MOCVD”), or the like. The thin layer may be any thin layer that may be deposited by the chemical vapor deposition method. For example, the thin layer may be a silicon-based thin layer, however, the disclosure is not limited thereto. For example, the first process chamber 16 may deposit the thin layer on the substrate through various deposition methods, and the thin layer may include a variety of materials such as inorganic materials, organic materials, metals, or the like.

The chamber CB may provide an internal space where the deposition process may be performed. For example, the chamber CB may be a reaction chamber including a reaction space therein. Various components that may be used in the deposition process may be disposed in the chamber CB. When performing the deposition process, a temperature inside the chamber CB may be relatively high. Accordingly, when the deposition process is performed, heat may be applied to the components disposed inside the chamber CB.

The stage ST may be disposed inside the chamber CB. The stage ST may be parallel to a plane defined by a first direction and a second direction intersecting the first direction. For example, the second direction may be perpendicular to the first direction. On the stage ST, the substrate may be disposed. The stage ST may support and fix the substrate.

The stage ST may move inside the chamber CB. For example, the stage ST may be able to move up and down in response to a loading time of the substrate, an unloading time of the substrate, and a time of performing the deposition process, or the like. In an embodiment, the stage ST may heat and maintain the substrate at a preset temperature. For example, the stage ST may include a heating member, or may be connected to the heating member. In addition, the stage ST may be connected to a power supply member and act as an electrode.

The deposition source SC may be disposed on the stage ST. The deposition source SC may be spaced apart from the stage ST in a third direction that crosses each of the first and second directions. For example, the third direction may be perpendicular to each of the first direction and the second direction. The deposition source SC may supply a deposition material into the chamber CB. In addition, the deposition source SC may be connected to the power supply member and act as an electrode.

In an embodiment, the deposition source SC may supply gas into the chamber CB. For example, the gas may include reaction gas, cleaning gas, or the like. For example, if a plasma is generated between the deposition source SC and the substrate in the chamber CB, the reaction gas may cause a chemical reaction using the energy of the plasma and be deposited on the substrate, and the cleaning gas may cause a chemical reaction using the energy of the plasma and be cleaned the components inside the chamber CB.

The mask MA may be disposed on the stage ST. For example, the mask MA may be disposed between the stage ST and the deposition source SC. The deposition material supplied from the deposition source SC may be deposited on the substrate by passing through the mask MA. The mask MA may have a pattern, and the deposition material may be deposited on the substrate in a corresponding pattern. The mask MA may include a metal. For example, the mask MA may include an alloy of nickel (“Ni”) and iron (“Fe”). For example, the mask MA may include an invar. However, the disclosure is not limited thereto.

The mask MA may face the substrate. For example, the mask MA and the substrate may be parallel to the plane defined by the first direction and the second direction, respectively, and the mask MA may be adjacent to the substrate in the third direction.

In an embodiment, the mask MA may define a plurality of openings OP that are arranged repeatedly along the first and second directions. Each of the openings OP may penetrate the mask MA in a thickness direction (i.e., in the third direction). The thin layer may be formed on the substrate in the corresponding pattern of the openings OP. A width of the openings OP may be determined in response to the pattern to be deposited.

The substrate may define a plurality of cell regions CA on which the thin layer is deposited. The pattern of cell regions CA may correspond to the pattern of openings OP. The cell regions CA may be arranged repeatedly along the first and second directions. Each cell region CA may correspond to the opening OP. Each cell region CA may correspond to a display device being manufactured.

FIGS. 1 and 2, the mask MA is shown to be spaced apart from the substrate by a certain gap, however, the disclosure is not limited thereto. For example, the mask MA may be arranged to contact the substrate.

In addition in FIG. 2, the openings OP and cell regions CA are shown to have a square shape on the plane, however, the disclosure is not limited thereto. For example, the shape of the openings OP and the cell regions CA may vary depending on the shape of the display device being manufactured.

For example, the plurality of process chambers included in the deposition quality control system of FIG. 1 may further include various components or some of the components may be omitted/modified.

For example, in FIG. 2, the first process chamber 16 is described as being a horizontal deposition device, however, the first process chamber 16 may also be a vertical deposition device. In this case, the stage ST, the mask MA, and the deposition source SC included in the vertical deposition device may be arranged in a direction which crosses the direction of gravity (e.g., in a direction parallel to the third direction).

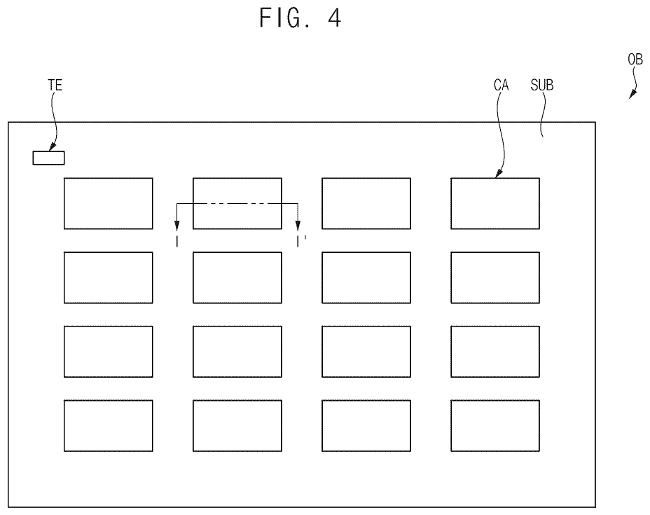

FIG. 4 is a plan view illustrating the deposition of FIG. 3.

Referring to FIG. 4, the substrate SUB may define cell regions CA arranged repeatedly along the first and second directions.

In an embodiment, the substrate SUB may define the cell regions CA arranged in i rows and j columns (i and j are natural numbers). In other words, the substrate SUB may define j cell regions CA arranged along the first direction in each row, and i cell regions CA arranged along the second direction in each column. The substrate SUB may define the n by m cell regions CA. Here, n and m are natural numbers.

In an embodiment, a test region TE may be defined in the substrate SUB. For example, the test region TE may be positioned in an outer portion of the substrate SUB (i.e., the outer portion of the cell regions CA). For example, the test region TE may be about 10 millimeters (mm) by about 12 mm in size. However, the disclosure is not limited thereto.

For example, the thickness gauge ELL included in the deposition quality control system 1 of FIG. 1 may inspect the deposition thickness of the encapsulation layer in the test region TE.

However, the disclosure is not limited thereto. For example, in FIG. 4, there is one the test region TE is described, however, the test region TE may also be defined as plural in another embodiment. In this case, the compensation accuracy may be greater compared to a case where only one test region TE is inspected.

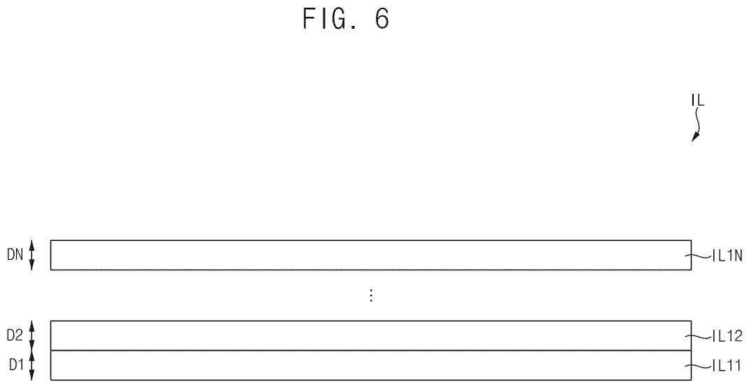

FIG. 5 is a cross-sectional view taken along line l-I′ of FIG. 4. FIG. 6 is a view illustrating a first inorganic encapsulation layer included in each of a plurality of cells of FIG. 5.

For example, a plurality of display devices may be formed on the substrate SUB of FIG. 4 and may be cut into each of display devices (e.g., cutting process). For example, FIG. 5 is a schematic cross-sectional view illustrating the display device manufactured using the deposition quality control system 1 of FIG. 1.

FIGS. 4, 5, and 6, in the cell regions CA and the test region TE, the display device may include a base substrate BSUB, a buffer layer BFR, a transistor TR, a gate insulating layer GI, an interlayer insulating layer ILD, a via insulating layer VIA, a light-emitting device LE, a pixel defining layer PDL, and an encapsulation layer TFE.

The transistor TR may include an active pattern ACT, a gate electrode GE, a first electrode SD1, and a second electrode SD2. The light-emitting device LE may include a pixel electrode PE, a light-emitting layer EL, and a common electrode CE.

The base substrate BSUB may include a transparent material or an opaque material. For example, the base substrate BSUB may include plastic, glass, quartz, or the like. For example, the base substrate BSUB may include polyimide. These may be used alone or in combination with each other.

The buffer layer BFR may be disposed on the base substrate BSUB and may prevent metal atoms, impurities, or the like from diffusing into the transistor TR. In addition, the buffer layer BFR may improve a flatness of a surface of the base substrate BSUB when the surface of the base substrate BSUB is not uniform. The buffer layer BFR may include an inorganic material such as silicon oxide (“SiOₓ”), silicon nitride (“SiNₓ”), silicon oxynitride (“SiOₓN_{y}”), or the like. These may be used alone or in combination with each other.

The active pattern ACT may be disposed on the buffer layer BFR. The active pattern ACT may include a source area, a drain area, and a channel area between the source area and the drain area. The active pattern ACT may include a silicon semiconductor material or an oxide semiconductor material. Examples of the silicon semiconductor material may include amorphous silicon, polycrystalline silicon, or the like. Examples of the oxide semiconductor material may include indium gallium zinc oxide (“IGZO”), indium tin zinc oxide (“ITZO”), or the like. These may be used alone or in combination with each other.

The gate insulating layer GI may be disposed on the active pattern ACT, and may cover the active pattern ACT. The gate insulating layer GI may include an inorganic material such as silicon oxide, silicon nitride, silicon oxynitride, or the like. These may be used alone or in combination with each other.

The gate electrode GE may be disposed on the gate insulating layer GI and the gate electrode GE may overlap the channel area of the active pattern ACT in a plan view. The gate electrode GE may include a metal, an alloy, a conductive metal nitride, a conductive metal oxide, a transparent conductive material, or the like. These may be used alone or in combination with each other.

The interlayer insulating layer ILD may be disposed on the gate electrode GE, and may cover the gate electrode GE. The interlayer insulating layer ILD may include an inorganic material such as silicon oxide, silicon nitride, silicon oxynitride, or the like. These may be used alone or in combination with each other.

The first electrode SD1 and the second electrode SD2 may be disposed on the interlayer insulating layer ILD. The first electrode SD1 may be connected to the source area of the active pattern ACT through a first contact hole penetrating the gate insulating layer GI and the interlayer insulating layer ILD. In addition, the second electrode SD2 may be connected to the drain area of the active pattern ACT through a second contact hole penetrating the gate insulating layer GI and the interlayer insulating layer ILD. For example, each of the first electrode SD1 and the second electrode SD2 may include a metal, an alloy, a conductive metal nitride, a conductive metal oxide, a transparent conductive material, or the like. These may be used alone or in combination with each other.

Accordingly, the transistor TR including the active pattern ACT, the gate electrode GE, the first electrode SD1, and the second electrode SD2 may be disposed on the base substrate BSUB.

The via insulating layer VIA may be disposed on the interlayer insulating layer ILD, and may cover the first electrode SD1 and the second electrode SD2. The via insulating layer VIA may include an organic material such as a phenol resin, an acrylic resin, a polyimide resin, a polyamide resin, a siloxane resin, an epoxy resin, or the like. These may be used alone or in combination with each other.

The pixel electrode PE may be disposed on the via insulating layer VIA. The pixel electrode PE may be connected to the second electrode SD2 through a contact hole penetrating the via insulating layer VIA. The pixel electrode PE may include a metal, an alloy, a conductive metal nitride, a conductive metal oxide, a transparent conductive material, or the like. These may be used alone or in combination with each other. For example, the pixel electrode PE may operate as an anode.

The pixel defining layer PDL may be disposed on the via insulating layer VIA, and may cover at least a portion of the pixel electrode PE. An opening exposing at least a portion of an upper surface of the pixel electrode PE may be defined in the pixel defining layer PDL. The pixel defining layer PDL may include an inorganic material or an organic material. For example, the pixel defining layer PDL may include an organic material such as an epoxy resin, a siloxane resin, or the like. In another embodiment, the pixel defining layer PDL may include an inorganic material or an organic material including a light blocking material having a black color.

The light-emitting layer EL may be disposed on the pixel electrode PE. The light-emitting layer EL may be disposed on the pixel electrode PE exposed by the pixel defining layer PDL. The light-emitting layer EL may include an organic material that emits light of a predetermined color.

The common electrode CE may be disposed on the light-emitting layer EL, where the common electrode CE may be a plate electrode. The common electrode CE may include a metal, an alloy, a conductive metal nitride, a conductive metal oxide, a transparent conductive material, or the like. These may be used alone or in combination with each other. For example, in an embodiment, the common electrode CE may operate as a cathode.

Accordingly, the light-emitting device LE including the pixel electrode PE, the light-emitting layer EL, and the common electrode CE may be disposed on the base substrate BSUB. The light-emitting device LE may be electrically connected to the transistor TR.

The encapsulation layer TFE may be disposed on the common electrode CE. The encapsulation layer TFE may protect the light-emitting device LE from external oxygen, moisture, or the like. In other words, in an embodiment, the light-emitting device LE may be disposed between the base substrate BSUB and the encapsulation layer TFE, and the light-emitting device LE may protect by the encapsulation layer TFE from external oxygen, moisture, or the like.

In an embodiment, the encapsulation layer TFE may include at least one inorganic layer and at least one organic layer. For example, the encapsulation layer TFE may have a structure in which inorganic layers and organic layers are alternately stacked.

For example, the encapsulation layer TFE may include), a first encapsulation layer (e.g., the first inorganic encapsulation layer IL1), a second encapsulation layer (e.g., an organic layer OL disposed on the first inorganic encapsulation layer IL1), and a third encapsulation layer (e.g., a second inorganic encapsulation layer IL2 disposed on the organic layer OL).

The first inorganic encapsulation layer IL1 and the second inorganic encapsulation layer IL2 may include an inorganic material such as silicon oxide, silicon nitride, silicon oxynitride, or the like. These may be used alone or in combination with each other.

The organic layer OL may include an organic material such as an acrylic resin, a polyimide resin, an epoxy resin, or the like. These may be used alone or in combination with each other. The organic layer OL may fill a defect of the first inorganic layer, or may be formed to flatten an upper surface. In addition, the light-emitting property of the organic light-emitting layer EL may be greater preserved as a moisture permeation path (e.g., a path through which the air, the moisture, or the like. penetrates into the organic light-emitting layer) becomes longer.

In an embodiment, the first inorganic encapsulation layer IL1 and the second inorganic encapsulation layer IL2 may be formed by using the deposition chamber 100 included in the deposition quality control system 1 of FIG. 1 (e.g., the first process chamber 16 of FIG. 2).

In an embodiment, the organic encapsulation layer OL may be formed by the inkjet chamber 500 included in the deposition quality control system 1 of FIG. 1.

In the above, it has been described that the inorganic encapsulation layer (the first inorganic encapsulation layer IL1) may be formed on the organic light-emitting layer EL, and the organic encapsulation layer OL may be formed on the inorganic encapsulation layer, however, the disclosure is not limited thereto. For example, the organic encapsulation layer OL may be formed on the organic light-emitting layer EL.

For example, as the substrate SUB on which the common electrode CE is formed passes through the deposition quality control system 1 of FIG. 1, the first inorganic encapsulation layer IL1, organic encapsulation layer OL, and the second inorganic encapsulation layer IL2 may be formed sequentially.

However, the disclosure is not limited thereto, and various insulating layers included in the display device, such as the buffer layer BFR, the gate insulating layer GI, the interlayer insulating layer ILD, or the like, may be formed by using the deposition quality control system 1. In addition, various thin layers included in the display device, such as the active pattern ACT, the gate electrode GE, the first electrode SD1, the second electrode SD2, the pixel electrode PE, the light-emitting layer EL, the common electrode CE, or the like, may be formed by using the deposition quality control system 1.

For example, in the deposition chamber 100 of FIG. 1, the first to (N)^{th} substrates may be sequentially entered. On the first to the (N)^{th} substrates, the first to (N)^{th} inorganic encapsulation layers may be formed sequentially.

As shown in FIG. 6, in an embodiment, the inorganic encapsulation layer IL (e.g., the first inorganic encapsulation layer IL1 and/or the second inorganic encapsulation layer IL2 of FIG. 5) may have a multi-layer structure. For example, each of the first to N^{th} inorganic encapsulation layers may have the multi-layer structure.

For example, the inorganic encapsulation layer IL may include sequentially formed a first layer IL11, a second laser IL12 to N^{th} layer IL1N on the base substrate (e.g., base substrate BSUB of FIG. 5. N is a natural number greater than or equal to 1.

For example, the first layer IL11 may have a first deposition thickness D1. The second layer IL12 may have a second deposition thickness D2. For example, the first deposition thickness D1 and the second deposition thickness D2 may be about thousands of Ångström, and the N^{th} deposition thickness DN may be about several hundred Ångström. However, the disclosure is not limited thereto.

The deposition quality control system 1 of FIG. 1 may compensate a deposition time using the deposition thicknesses D1˜DN measured by the ellipsometer.

In an embodiment, the controller (e.g., the first controller 300)) may derive a first compensation time of the deposition time forming the first inorganic layer positioned closest (most adjacent) to the organic light-emitting layer among the multi-layer structure and a second compensation time of the deposition time forming the second inorganic layer on the first inorganic layer.

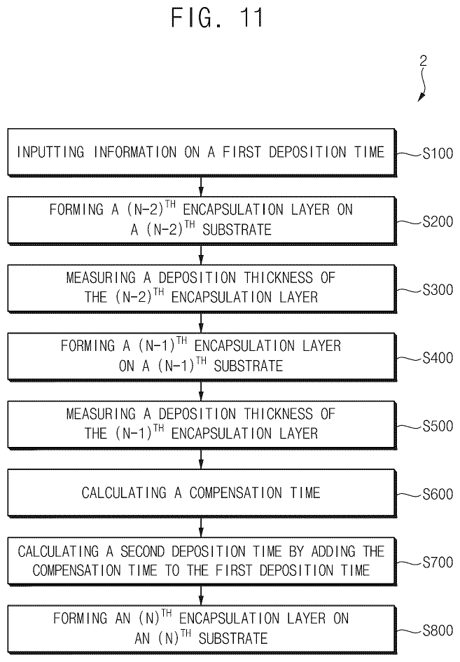

However, the disclosure is not limited thereto. In an embodiment, the controller may calculate the compensation time of the deposition time to form a single inorganic layer positioned most adjacent to the organic light-emitting layer in the multi-layer structure. For another example, the deposition quality control system may compensate for the deposition time of forming three or more layers. Detailed descriptions of the compensation will be described below with reference to FIG. 11 et seq.

FIG. 7 is a view illustrating a thickness gauge of FIG. 1.

Referring to FIGS. 1, 6 and 7, in an embodiment, the thickness gauge ELL (e.g., ellipsometer) may be positioned in the logistics chamber 200. In an embodiment, each of the D1 and the D2 may be derived from the measured values of the ellipsometer.

For example, the ellipsometer may include a gantry IS, a polarization generator 302, and a polarization analyzer 304.

For example, the gantry IS may move in a vertical direction. Accordingly, the distance between the deposition object OB and the polarization generator 302 may be adjusted. For example, each of the first to (N)^{th} substrates in which the deposition process has been completed sequentially may be transported to a position adjacent to the ellipsometer. The ellipsometer may be moved vertically to a position adjacent to the first to (N)^{th} substrates. (e.g., the ellipsometer may be moved in a way such that the light emitted from the polarization generator 302 included in the ellipsometer incident in the test region TE of FIG. 4). Thereafter, the ellipsometer may measure the deposition thickness of the first inorganic encapsulation layer (e.g., the first inorganic encapsulation layer IL1 of FIG. 5) formed on the first to (N)^{th} substrates.

For example, the gantry IS may include a first guide 204, a second guide 206, a longitudinal support 208, a first coupler 212, and a second coupler 214.

For example, first coupler 212 may be coupled to first guide 204. For example, the polarization generator 302 may be disposed in the first coupler 212.

For example, the second coupler 214 may be coupled to the second guide 206. For example, the polarization analyzer 304 may be disposed in the second coupler 214.

For example, the first guide 204 and the second guide 206 may have an arc shape. Accordingly, the polarization generator 302 and polarization analyzer 304 may move along a trajectory of the arc shape. For example, the polarization generator 302 and the polarization analyzer 304 may move an equal distance from each other in opposite directions relative to the longitudinal support 208.

For example, the longitudinal support 208 may be extended in the direction of gravity. For example, the longitudinal support 208 may be connected to the first guide 204 and the second guide 206. In addition, the longitudinal support 208 may accommodate lines connected to the polarization generator 302 and polarization analyzer 304.

For example, polarization generator 302 may include a light source, a linear polarizer, and a compensator.

For example, the light source may emit light. For example, the light source may emit visible light. However, the disclosure is not limited thereto. For example, the light source may emit light of varying bandwidths from ultraviolet (“UV”) band to infrared (“IR”) band. In addition, the light source may emit light of a single wavelength, or multiple wavelengths.

For example, the linear polarizer may linearly polarize the light emitted from the light source. The linear polarizer may be positioned on a path of the light emitted from the light source. The linear polarizer may be rotated. Accordingly, the linear polarizer may adjust the polarization direction of the light emitted from the light source.

For example, the compensator may adjust a phase difference of light passing through the linear polarizer. The compensator may be positioned in a path of the light passing through the linear polarizer. The compensator may be rotated. Accordingly, the compensator may adjust a polarization state (e.g., the phase difference between p and s waves) of the incident light on the deposition object OB.

That is, the light emitted from the light source may pass through the linear polarizer and the compensator and have a certain polarization state. Light with the certain polarization state may be incident on the deposition object OB. The light reflected from the deposition object OB (i.e., reflected light) may be transmitted to analyzer 216. For example, the analyzer 216 may be a charge coupled device (“CCD”) camera. However, The disclosure is not limited thereto. For example, the analyzer 216 may be connected to the first controller 300 of FIG. 1.

However, the disclosure is not limited thereto. For example, the thickness gauge ELL included in the deposition quality control system of FIG. 6 may include a variety of additional components, or some of the components may be omitted/modified.

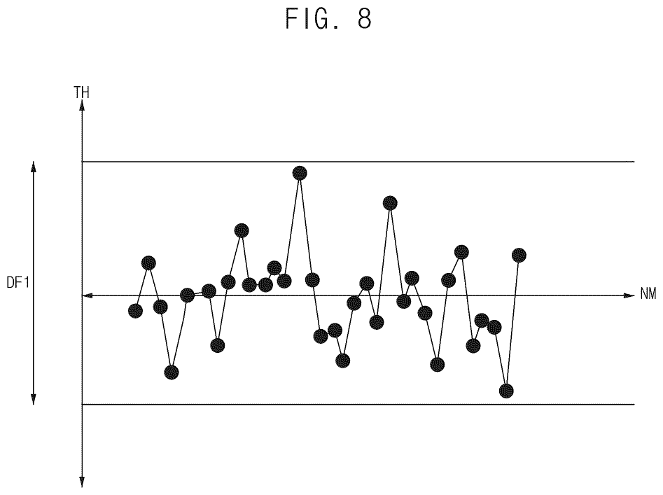

FIGS. 8, 9, and 10 are views illustrating an effect of the deposition quality control system of FIG. 1.

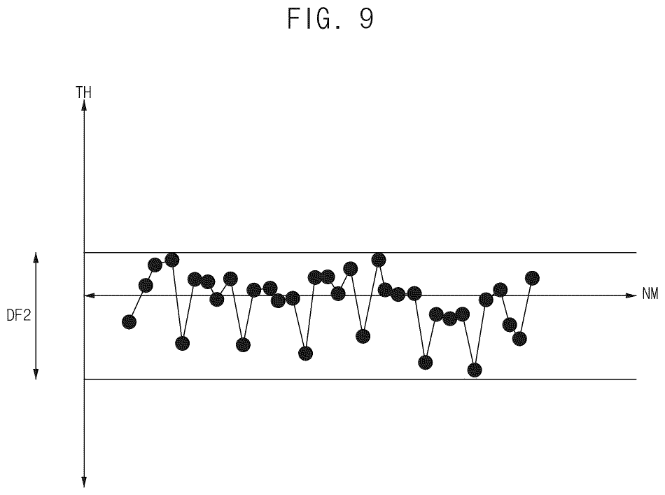

For example, FIGS. 8 and 9 illustrate the deviation between mother substrates before and after the application of the deposition quality control system of FIG. 1.

Referring to FIGS. 1, 8, and 9, X-axis denotes a number NM of the mother substrate that passed through the thickness gauge ELL sequentially, and Y-axis denotes a deposition thickness TH (e.g., the first deposition thickness D1 of FIG. 6), of the first inorganic encapsulation layer (e.g., the first inorganic encapsulation layer IL1) measured by the thickness gauge ELL.

In the conventional deposition quality control system (refer to FIG. 8), the deposition object OB passes through the thickness gauge ELL after forming the second inorganic encapsulation layer (e.g., the second inorganic encapsulation layer IL2 of FIG. 5). In this case, after forming the first inorganic encapsulation layer, the organic encapsulation layer, and the second inorganic encapsulation layer (after about one and a half to two hours), the deposition thickness of the first inorganic encapsulation layer was measured.

In the deposition chamber, layer quality may gradually become porous due to the heat. Accordingly, a thickness deviation DF1 of the first inorganic encapsulation layer between the mother substrates was large.

In addition, in the conventional deposition quality control system, a process time increased when a total inspection was carried out, the thickness deviation DF1 was large due to a sampling inspection (e.g., about 9% inspection).

Accordingly, in the conventional deposition quality control system, it was difficult to ensure uniform display quality.

As described above referring to FIG. 1, in a case of a deposition quality control system 1 according to an embodiment of the disclosure, the deposition thickness of two mother substrates (e.g., the deposition object OB of FIG. 1) may be measured, and the next deposition time of the deposition object to be performed may be determined. By determining the deposition time of the next mother substrate based on the two mother substrates, the deviation among the mother substrates (e.g., a thickness deviation DF2 of the first inorganic encapsulation layer between the mother substrates of FIG. 9) may be minimized. By minimizing the thickness deviation between the mother substrates, the VACs (view angle color shift) property may be improved. For example, the VA Cs property may mean the property that the color appears differently depending on the angle. The VA Cs property may vary depending on the layer thickness uniformity of interface where light emitted from the light-emitting device (e.g., light-emitting device LE of FIG. 5) meet first. In order to equalize the deposition thickness, to adjust the deposition time may be important.

For example, as a result of applying the deposition quality control system 1 according to an embodiment of the disclosure, the thickness deviation DF1 about 3% was reduced to the thickness deviation DF2 of about 1.8%.

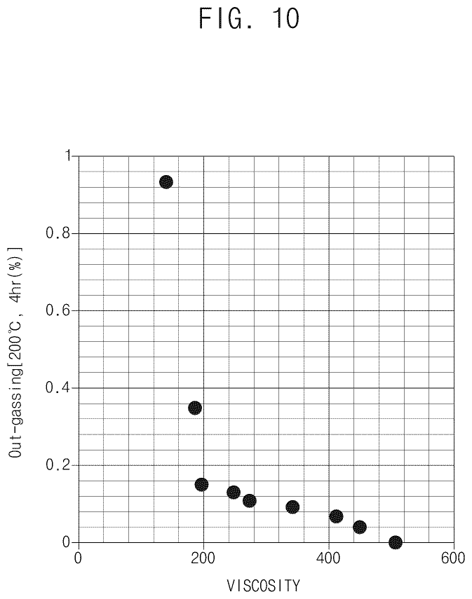

In addition, referring to FIG. 10, the deposition quality control system 1 of FIG. 1 may prevent the scattering of grease on the mother substrate by using the fume-free grease or lubrication-free driving device (e.g., a linear driving device driven by the magnetic method) when the ellipsometer is driven. Accordingly, the occurrence of the un-filled defect in the subsequent process (e.g., the inkjet process) using the grease may be prevented, and the reduction of yield (e.g., the reduction of yield due to the disposal of the display device which is of poor reliability) may be prevented.

In an embodiment, the ellipsometer may operate using grease with the viscosity of about 500 to about 600 pascal-seconds.

For example, if the viscosity is less than about 500 pascal-seconds, the grease may be scattered on the mother substrate. Accordingly, the un-filled defect may occur.

On the other hand, if the viscosity exceeds about 600, the driving device may be overloaded due to excessive viscosity. Accordingly, the operation of the ellipsometer may be difficult (e.g., in an event of a breakdown, or the like.).

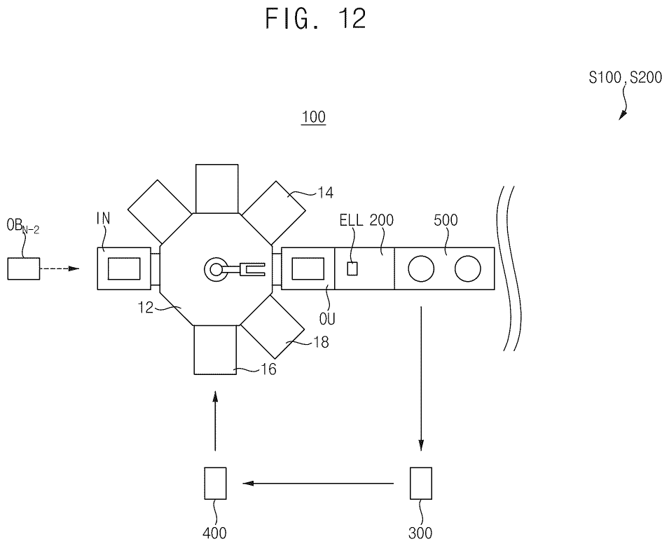

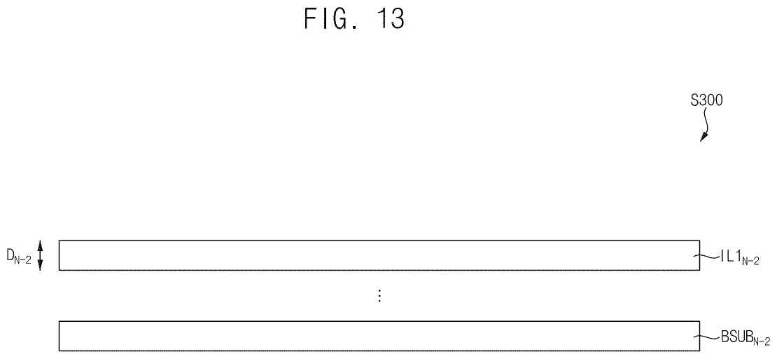

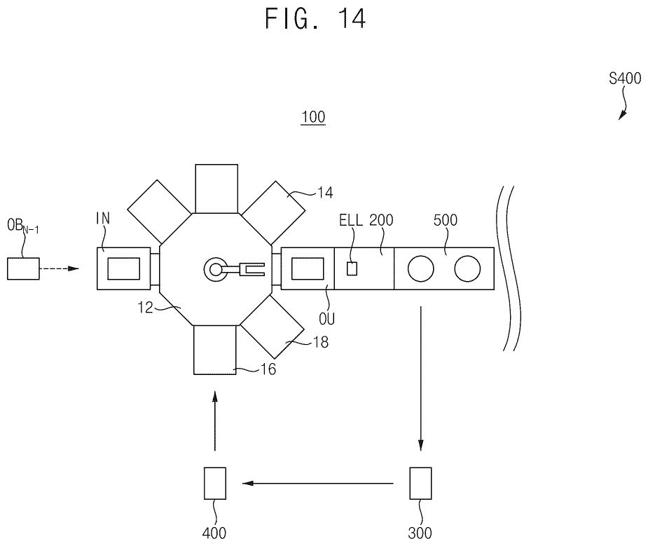

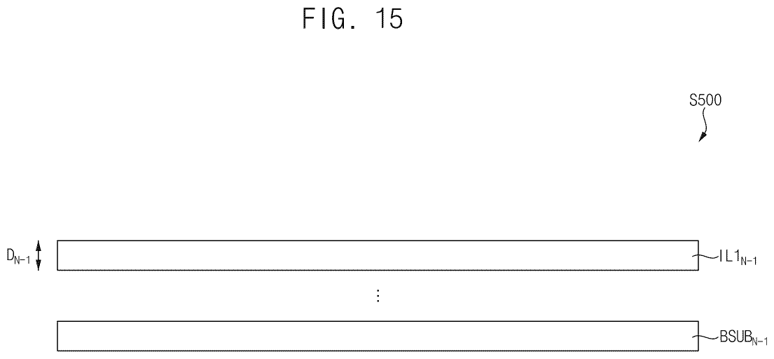

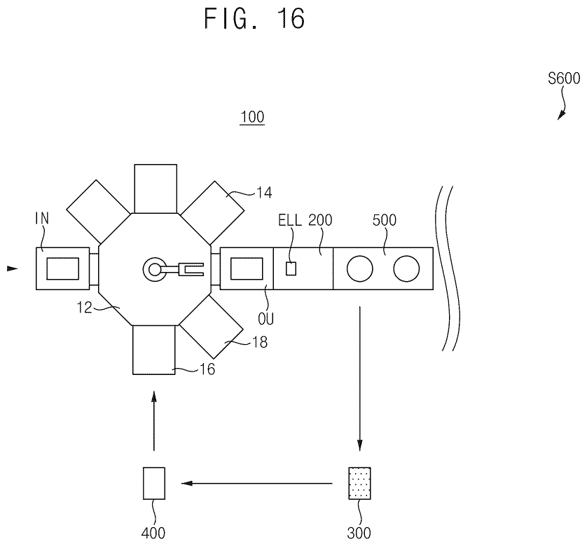

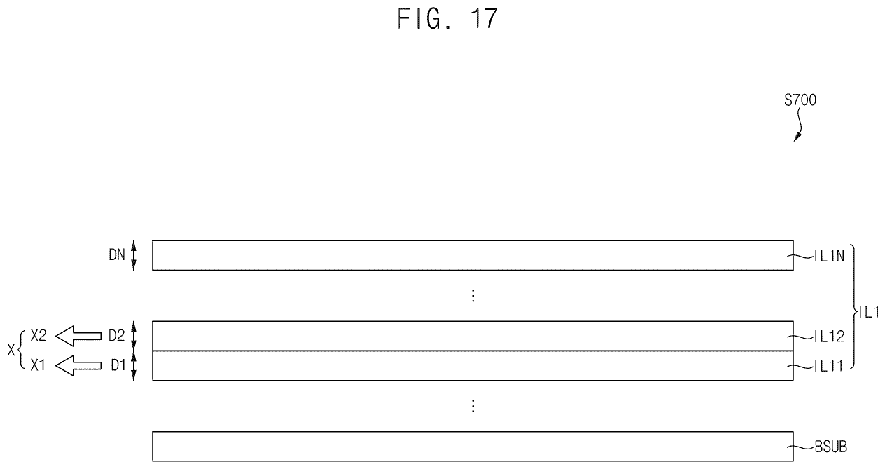

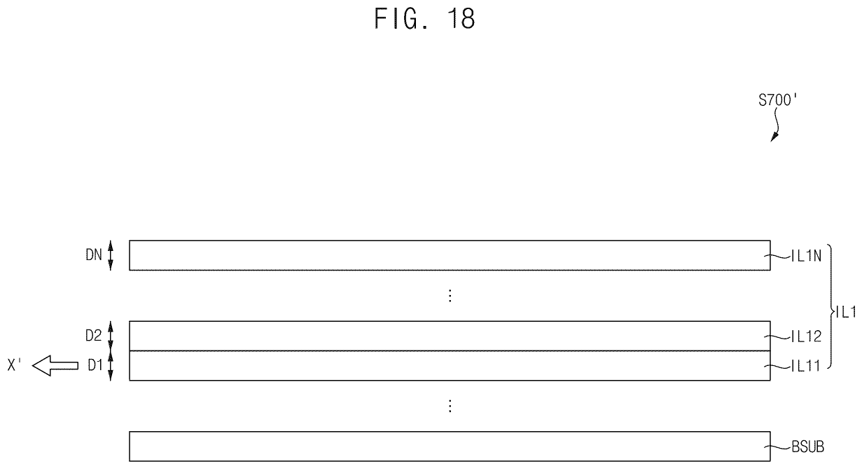

FIG. 11 is a flowchart is illustrating a deposition quality control method according to an embodiment of the disclosure. FIGS. 12, 13, 14, 15, 16, 17, 18, 19, and 20 are views illustrating the deposition quality control method of FIG. 11.

Hereinafter, for convenience of description, any repetitive detailed descriptions of the same or like elements as those of the deposition quality control system 1 described above with reference to FIGS. 1, 2, 3, 4, 5, 6, 7, 8, 9, and 10 will be omitted or simplified.

Referring to FIGS. 11, 12, and 13, a deposition quality control method 2 according to an embodiment of the disclosure may include inputting information on a first deposition time (S100); forming an (N−2)^{th} encapsulation layer IL1_{N-2} on a (N−2)^{th} substrate BSUB_{N-2} during the first deposition time (S200); and measuring a deposition thickness D_{N-2} of the (N−2)^{th} encapsulation layer IL1_{N-2} (S300). (N)^{th} being a natural number greater than or equal to three)

For example, if the N=3, the first deposition time may mean an initial deposition time. For example, if the N=4 or more, the first deposition time may mean the deposition time reflecting the compensation time.

In an embodiment, the (N−2) object to be processed OB_{N-2} may be enter into the deposition chamber 100 after the organic light-emitting layer (e.g., the organic light-emitting layer EL of FIG. 5) is formed on the (N−2) substrate BSUB_{N-2} during the first deposition time.

In an embodiment, in the deposition chamber 100, the (N−2) object to be processed OB_{N-2} may include the encapsulation layer (e.g., the (N−2)^{th} encapsulation layer IL1_{N-2}) to cover the organic light-emitting layer (e.g., the organic light-emitting layer EL of FIG. 5) on the (N−2)^{th} substrate BSUB_{N-2}.

In an embodiment, the (N−2)^{th} encapsulation layer IL1_{N-2} covering the organic light-emitting layer may include inorganic material

In an embodiment, the deposition thickness D_{N-2} of the (N−2)^{th} encapsulation layer IL1_{N-2} may be measured by the ellipsometer. In an embodiment, the ellipsometer may be driven at the position adjacent to the (N−2)^{th} substrate BSUB_{N-2} to measure the deposition thickness D_{N-2} of the (N−2)^{th} encapsulation layer IL1_{N-2}.

Referring to FIGS. 11, 14, and 15, in an embodiment, the deposition quality control method 2 may forms the (N−1)^{th} encapsulation layer IL1_{N-1} on the (N−1)^{th} substrate BSUB_{N-1} (S400), and the deposition thickness D_{N-1} of the (N−1)^{th} encapsulation layer IL1_{N-1} may be measured (S500).

The (N−1)^{th} object to be processed OB_{N-1} may enter into the deposition chamber 100 after the (N−2)^{th} object to be processed OB_{N-2}.

In an embodiment, in the deposition chamber 100, the (N−1) object to be processed OB_{N-1} may include the encapsulation layer (e.g., the (N−1)^{th} encapsulation layer IL1_{N-1}) to cover the organic light-emitting layer (e.g., the organic light-emitting layer EL of FIG. 5) on the (N−1)^{th} substrate BSUB_{N-1}.

In an embodiment, the deposition thickness D_{N-1} of the (N−1)^{th} encapsulation layer IL1_{N-1} may be measured by the ellipsometer. In an embodiment, the ellipsometer may be driven at the position adjacent to the (N−1)^{th} substrate BSUB_{N-1} to measure the deposition thickness D_{N-1} of the (N−1)^{th} encapsulation layer IL1_{N-1}.

Referring to FIGS. 11, 16, and 17, calculate the compensation time X which satisfies Equation 1 and Equation 2 below (S600); and calculate the second deposition time by adding the compensation time X to the first deposition time (S700).

$$Y = AX + B \qquad < Equation 1 >$$

In Equation 1, Y denotes the (target) thickness of the (N)^{th} encapsulation layer, A denotes deposition rate, and X denotes the compensation time.

$$B = α * {D}_{2} + ( 1 - α ) * {D}_{1} . \qquad < Equation 2 >$$

In an embodiment, the encapsulation layer (e.g., the (N−2)^{th} encapsulation layer IL1_{N-2} and/or the (N−1)^{th} encapsulation layer IL1_{N-1}) may have the multi-layer structure. For example, the organic light-emitting layer may form on a mother substrate, and the encapsulation layer having the multi-layered structure on the organic light-emitting layer (e.g., the first inorganic encapsulation layer IL1). The first inorganic encapsulation layer IL1 may include sequentially formed the first layer IL11, the second layer IL12 to the N^{th} layer IL1N

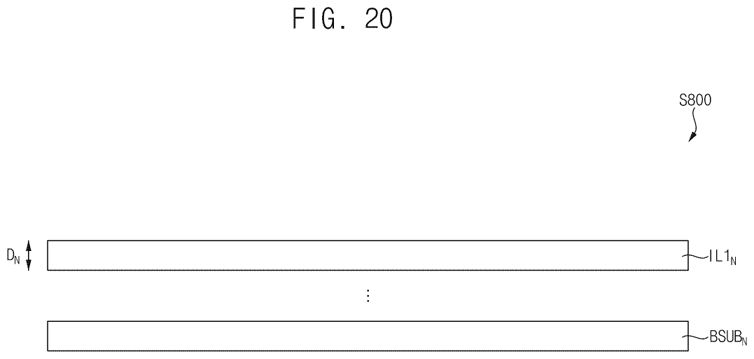

As described above, even if information the first deposition time is inputted, the deposition thickness may be changed in the process of the deposition process being performed on the mother substrates sequentially enter into the deposition chamber 100. Accordingly, deviation among the mother substrates (refer to FIG. 8) may occur among the mother substrates. The deposition quality control method 2 according to an embodiment of the disclosure may minimize the deviation among the mother substrates by continuously compensating the target thickness (e.g., the deposition thickness DN of the N^{th} encapsulation IL1_{N} of FIG. 20) for each of the mother substrates.

For example, if the N=3, based on the deposition thicknesses of the first object to be processed and the second object to be processed sequentially enter into the deposition chamber 100, the deposition time of the third object to be processed to be entered into the deposition chamber 100 may be compensated.

For example, if the N=4, based on the deposition thicknesses of the second object to be processed and the third object to be processed sequentially enter into the deposition chamber 100, the deposition time of the fourth object to be processed to be entered into the deposition chamber 100 may be compensated.

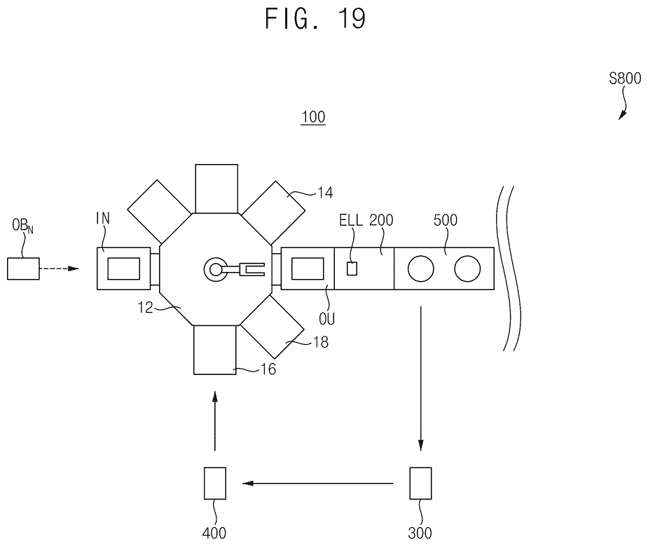

For example, the first layer IL11 may have the first deposition thickness D1, the second layer IL12 may have the second deposition thickness D2, and the N^{th} layer IL1N may have the N^{th} deposition thickness DN. For example, if the thickness uniformity of the first deposition thickness D1 and the second deposition thickness D2 is also greatly affected by the VACs (view angle color shift) property of the organic light-emitting layer, the deposition quality control method 2 may compensate the deposition time of the first to second layers formed on the mother substrate (e.g., the substrate included in the object to be processed OB_{N} of FIG. 19) to be performed based on the first deposition thickness D1 and the second deposition thickness D2.

In this case, in an embodiment, the compensation time X may include the first compensation time X1 of the deposition time forming the first layer IL11 positioned most adjacent to the organic light-emitting layer among the multi-layer structure and the second compensation time X2 of the deposition time forming the second layer IL12 on the first layer IL11. However, the disclosure is not limited thereto.

Referring to FIGS. 11, 16, and 18, in another embodiment, a compensation time X′ may be calculated (S600), and the second deposition time may be calculated by adding the compensation time X′ to the first deposition time (S700).

In an embodiment, the encapsulation layer (e.g., the (N−2)^{th} encapsulation layer IL1_{N-2} and/or the (N−1)^{th} encapsulation layer IL1_{N-1}) may have the multi-layer structure. For example, the organic light-emitting layer may form on the mother substrate (e.g., BSUB), and the encapsulation layer (e.g., the first inorganic encapsulation layer IL1) having the multi-layered structure on the organic light-emitting layer. For example, the first inorganic encapsulation layer may include the sequentially formed the first layer IL11, the second layer IL12 to N^{th} layer IL1N on the mother substrate.

For example, the first layer IL11 may have the first deposition thickness D1, the second layer IL12 may have the second deposition thickness D2, and the N^{th} layer IL1N may have the N^{th} deposition thickness DN. For example, if the thickness uniformity of the first deposition thickness D1 is also greatly affected by the VACs (view angle color shift) property of the organic light-emitting layer, the deposition quality control method 2 may be used to compensate the deposition time of the first layer formed on the mother substrate (e.g., the substrate included in the object to be processed OBN of FIG. 19, BSUB) to perform the next deposition process based on the first deposition thickness D1.

In this case, in an embodiment, the compensation time X may include only the compensation time X′ of the deposition time forming the layer positioned most adjacent to the organic light-emitting layer in the multi-layer structure (e.g., the first layer IL11).

Referring to FIGS. 19 and 20, the N^{th} encapsulation layer may be formed on the N^{th} substrate during the second deposition time (S800).

The N^{th} object to be processed OBN may be entered into the deposition chamber 100 after the (N−1)^{th} object to be processed OB_{N-1}.

In an embodiment, in the deposition chamber 100, the N^{th} object to be processed OBN may form the encapsulation layer (e.g., the (N)^{th} encapsulation layer IL1_{N}) to cover the organic light-emitting layer (e.g., the organic light-emitting layer EL of FIG. 5) on the (N)^{th} substrate BSUB_{N}.

In an embodiment, the (N)^{th} encapsulation layer IL1_{N} covering the organic light-emitting layer may include inorganic material

In an embodiment, the deposition thickness DN of the (N)^{th} encapsulation layer IL1_{N} may be measured by the ellipsometer. In an embodiment, the ellipsometer may be driven at the position adjacent to the (N)^{th} substrate BSUB_{N} to measure the deposition thickness DN of the (N)^{th} encapsulation layer IL1_{N}.

Next, as shown in FIG. 5, the inkjet process may be performed to discharge organic material onto the first to N^{th} substrates. Through this, as shown in FIG. 5, the encapsulation layer including the organic material may be additionally formed on the encapsulation layer including the inorganic material.

As described above, the deposition quality control method 2 according to an embodiment of the disclosure may measure the deposition thickness of the encapsulation layer including the inorganic material immediately after forming the encapsulation layer including the inorganic material (e.g., within about 5 minutes), and the deposition time may be compensated based on the deposition thickness to minimize the thickness deviation among the mother substrates. By minimizing the thickness deviation between the mother substrates, the VACs (view angle color shift) property may be improved.

In addition, the deposition quality control method 2 may prevent the scattering of grease on the mother substrate by using the fume free grease or the lubrication free driving device (e.g., the linear driving device by magnetic method). Accordingly, the occurrence of the un-filled defect in the subsequent process (e.g., the inkjet process) using the grease may be prevented, and the reduction of yield (e.g., the reduction of yield due to the disposal of the display device which is of poor reliability) may be prevented.

The deposition quality control system in the embodiments may be applied to a manufacturing process of a display device included in a computer, a notebook, a mobile phone, a smartphone, a smart pad, a portable media player (“PMP”), a personal digital assistance (“PDA”), an MP3 player, or the like.

The invention should not be construed as being limited to the embodiments set forth herein. Rather, these embodiments are provided so that this disclosure will be thorough and complete and will fully convey the concept of the invention to those skilled in the art. While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition quality control method comprising:
inputting information on a first deposition time;
forming a (N−2)^{th} encapsulation layer on a (N−2)^{th} substrate during the first deposition time;
measuring a deposition thickness of the (N−2)^{th} encapsulation layer;
forming a (N−1)^{th} encapsulation layer on a (N−1)^{th} substrate during the first deposition time;
measuring a deposition thickness of the (N−1)^{th} encapsulation layer;
calculating a compensation time which satisfies Equation 1 and Equation 2 below;
calculating a second deposition time by adding the compensation time to the first deposition time; and
forming an (N)^{th} encapsulation layer on an (N)^{th} substrate during the second deposition time, (N)^{th} being a natural number greater than or equal to three,
$$Y = AX + B , \qquad < Equation 1 >$$
wherein in Equation 1, Y denotes a deposition thickness of the (N)^{th} encapsulation layer, A denotes a deposition rate, and X denotes the compensation time,
$$B = α * {D}_{2} + ( 1 - α ) * {D}_{1} , \qquad < Equation 2 >$$
wherein in Equation 2, D2 denotes the thickness of the (N−1)^{th} encapsulation layer, D1 denotes the thickness of the (N−2)^{th} encapsulation layer, and α denotes a weighted value.

2. The deposition quality control method of claim 1, wherein, each of the (N−2)^{th} to (N)^{th} encapsulation layers is formed of inorganic material.

3. The deposition quality control method of claim 2, further comprising:
forming an organic light-emitting layer between each of the (N−2)^{th} substrate to the (N)^{th} substrate and a corresponding encapsulation layer, and
wherein the organic light-emitting layer is covered by the corresponding encapsulation layer.

4. The deposition quality control method of claim 3, wherein each of the (N−2)^{th} to (N)^{th} encapsulation layers has a multi-layer structure.

5. The deposition quality control method of claim 4, wherein the compensation time includes a first compensation time of a deposition time to form a first layer positioned most adjacent to the organic light-emitting layer among layers in the multi-layer structure and a second compensation time of the deposition time to form a second layer on the first layer among the layers in the multi-layer structure.

6. The deposition quality control method of claim 4, wherein the compensation time includes a compensation time of a deposition time to form a layer most adjacent to the organic light-emitting layer among layers in the multi-layer structure.

7. The deposition quality control method of claim 1, further comprising:
performing an inkjet process, which discharges an organic material on the (N−2)^{th} to (N)^{th} substrates, after the forming the (N)^{th} encapsulation layer.

8. The deposition quality control method of claim 1, wherein, each of the D1 and the D2 is derived from a measured value of an ellipsometer.

9. The deposition quality control method of claim 8, wherein,
the ellipsometer operates in a position adjacent to each of the (N−2)^{th} to (N)^{th} substrates, and
the ellipsometer measures the deposition thickness of each of the (N−2)^{th} to (N)^{th} encapsulation layers.

10. The deposition quality control method of claim 9, wherein the ellipsometer operates using grease with a viscosity of about 500 to about 600 pascal-seconds.

11. A deposition quality control system comprising:
a deposition object including a substrate;
a deposition chamber, which forms a first encapsulation layer on the substrate during a deposition time;
a logistics chamber, which transports the deposition object after the formation of the first encapsulation layer;
a thickness gauge, which measures a deposition thickness of the first encapsulation layer positioned in the logistics chamber; and
a controller, which receives the deposition thickness of the first encapsulation layer from the thickness gauge and compensates the deposition time.

12. The deposition quality control system of claim 11, wherein,
the deposition object after the formation includes a (N−2)^{th} object, a (N−1)^{th} object, and a (N)^{th} object,
the (N−2)^{th} object includes a (N−2)^{th} encapsulation layer on a (N−2)^{th} substrate therein;
the (N−1)^{th} object includes a (N−1)^{th} encapsulation layer on a (N−1)^{th} substrate therein,
the (N)^{th} object includes an (N)^{th} encapsulation layer on a (N−1)^{th} substrate therein, and
each of the (N−2)^{th} encapsulation layer, the (N−1)^{th} encapsulation layer, and the (N)^{th} encapsulation layer includes an inorganic material.

13. The deposition quality control system of claim 12, wherein the controller
receives information on a first deposition time as an input;
commends to form the (N−2)^{th} encapsulation layer on the (N−2)^{th} substrate during the first deposition time;
commends to measure a deposition thickness of the (N−2)^{th} encapsulation layer;
commends to form the (N−1)^{th} encapsulation layer on the (N−1)^{th} substrate during the first deposition time;
commends to measure a deposition thickness of the (N−1)^{th} encapsulation layer;
calculates a compensation time which satisfies Equation 1 and Equation 2 below;
calculates a second deposition time by adding the compensation time to the first deposition time; and
commends to form the (N)^{th} encapsulation layer on the (N)^{th} substrate during the second deposition time, (N)^{th} being a natural number greater than or equal to three,
$$Y = AX + B , \qquad < Equation 1 >$$
wherein in Equation 1, Y denotes a deposition thickness of the (N)^{th} encapsulation layer, A denotes a deposition rate, and X denotes the compensation time,
$$B = α * {D}_{2} + ( 1 - α ) * {D}_{1} , \qquad < Equation 2 >$$
wherein in Equation 2, D2 denotes the thickness of the (N−1)^{th} encapsulation layer, D1 denotes the thickness of the (N−2)^{th} encapsulation layer, and α denotes a weighted value.

14. The deposition quality control system of claim 13,
the deposition object after the formation further includes an organic light-emitting layer between each of the (N−2)^{th} substrate to the (N)^{th} substrate and a corresponding encapsulation layer, and
wherein the organic light-emitting layer is covered by the first to the corresponding encapsulation layer.

15. The deposition quality control system of claim 13, wherein each of the D1 and the D2 is derived from a measured value of an ellipsometer.

16. The deposition quality control system of claim 15, wherein grease viscosity used for the ellipsometer operation is about 500 to about 600 pascal-seconds.

17. The deposition quality control system of claim 12, wherein each of the (N−2)^{th} encapsulation layer, the (N−1)^{th} encapsulation layer, and the (N)^{th} encapsulation layer has a multi-layer structure.

18. The deposition quality control system of claim 17, wherein the controller derives a first compensation time of a deposition time to form a first layer positioned most adjacent to the organic light-emitting layer among layers in the multi-layer structure and a second compensation time of the deposition time to form a second layer on the first layer among the layers in the multi-layer structure.

19. The deposition quality control system of claim 17, wherein the controller derives a compensation time of a deposition time to form an inorganic layer positioned most adjacent to the organic light-emitting layer among layers in the multi-layer structure.

20. The deposition quality control system of claim 11, further comprising:
an inkjet chamber, which forms an organic encapsulation layer including an organic material on the deposition object after measuring the deposition thickness.
